(19) United States
(12) Patent Application Publication
(10) Pub. No.: US 2024/0106342 A1
(43) Pub. Date: Mar. 28, 2024

(54) HALF-BRIDGE POWER DEVICE AND HALF-BRIDGE POWER MODULE

(71) Applicant: ZF Friedrichshafen AG, Friedrichshafen (DE)

(72) Inventors: Zhiwu Hu, Shanghai (CN); Tianyuan Dong, Shanghai (CN); Zhao Li, Shanghai (CN)

(73) Assignee: ZF Friedrichshafen AG, Friedrichshafen (DE)

(21) Appl. No.: 18/477,243

(22) Filed: Sep. 28, 2023

(30) Foreign Application Priority Data
Sep. 28, 2022 (CN) 202222577641.6

(51) Int. Cl. H02M 7/00; H01L 23/00; H01L 23/498; H01L 25/07; H02M 7/5387

(52) U.S. Cl. CPC H02M 7/003; H01L 23/49811; H01L 24/37; H01L 24/40; H01L 24/45; H01L 24/48; H01L 24/73; H01L 25/072; H02M 7/5387; H01L 2224/37147; H01L 2224/40137; H01L 2224/40225; H01L 2224/45124; H01L 2224/48091; H01L 2224/48225; H01L 2224/73271

(57) ABSTRACT

A half-bridge power device includes a module substrate, the upper surface of which includes a first half-bridge area, a second half-bridge area, a first half-bridge lead-out area, and a second half-bridge lead-out area, which are separate, the first and second half-bridge lead-out areas being located at the ends of the module substrate. The first and second half-bridge power chips are connected to the first half-bridge area and the second half-bridge area, respectively. The first, second, and third power connector terminals are connected to the first and second half-bridge areas, and the first and second half-bridge power chips to form a power loop.

### CROSS-REFERENCE TO RELATED APPLICATION

This application claims priority to Chinese Application No. 202222577641.6, filed on Sep. 28, 2022, the entirety of which is hereby fully incorporated by reference herein.

### FIELD

The present disclosure relates to the field of power electronic technologies and, more particularly, to a half-bridge power device and half-bridge power module assembly.

### BACKGROUND

Half-bridge power devices and half-bridge power module assemblies are commonly used in electrical equipment, and how to increase convenience and functional stability during the engineering realization of products (including during production, installation and use) when realizing electrical functions with the use of half-bridge power devices and half-bridge power module assemblies—is a topic that needs to be addressed. Specifically, how to reduce stray inductance in the actual circuit structure and how to enhance the stability of the structure and facilitate production are problems to be solved.

### SUMMARY

The present disclosure aims to achieve high efficiency, convenience and stability for manufacture and use of half-bridge power devices and half-bridge power module assemblies by providing a half-bridge power device and half-bridge power module assembly.

To this end, the present disclosure provides a half-bridge power device comprising:
a module substrate, the upper surface of the module substrate including a first half-bridge area, a second half-bridge area, a first half-bridge lead-out area and a second half-bridge lead-out area, which are separate, the first half-bridge lead-out area and the second half-bridge lead-out area being located at the ends of the module substrate, respectively;
half-bridge power chips, including a first half-bridge power chip and a second half-bridge power chip; the first half-bridge power chip and the second half-bridge power chip being pasted to the first half-bridge area and the second half-bridge area, respectively;
power connector terminals, including a first power connector terminal, a second power connector terminal and a third power connector terminal; the first power connector terminal, the second power connector terminal and the third power connector terminal being connected to the first half-bridge area, the second half-bridge area, the first half-bridge power chip and the second half-bridge power chip to form a power loop of the half-bridge power device;
a first end of the first power connector terminal is connected to a DC positive electrode (DC+) through a positive busbar and extended beyond a first end of the module substrate, a second end of the third power connector terminal is connected to a DC negative electrode (DC−) and extended beyond a first end of the module substrate; the positive busbar is located above the third power connector terminal, and a second end of the positive busbar and the second end of the third power connector terminal have a first height difference.

In an embodiment of the present disclosure:
a second end of the first power connector terminal is connected to the first half-bridge power area and also connected to a drain electrode of the first half-bridge power chip;
a first end of the second power connector terminal is connected to a source electrode of the first half-bridge power chip, a second end of the second power connector terminal serves as an alternating current (AC) output terminal of the half-bridge power device, a third end of the second power connector terminal is connected to the second half-bridge area and also connected to a drain electrode of the second half-bridge power chip, the second end of the second power connector terminal is extended beyond a second end of the module substrate;
a first end of the third power connector terminal is connected to a source electrode of the second half-bridge power chip.

In an embodiment of the present disclosure, when the first half-bridge power chip includes a plurality of first chips, the first end of the second power connector terminal is divided into multiple connecting pins which are connected to the source electrodes of the plurality of first chips, respectively; the connection location between the second end of the first power connector terminal and the first half-bridge power area is situated in an area between two connecting pins among the multiple connecting pins.

In an embodiment of the present disclosure, when the second half-bridge power chip includes a plurality of second chips, the first end of the third power connector terminal is divided into multiple connecting pins which are connected to the source electrodes of the plurality of second chips.

In an embodiment of the present disclosure, the connection of the first half-bridge power chip and the second half-bridge power chip to the first half-bridge lead-out area and the second half-bridge lead-out area 114, respectively, includes:
a gate electrode of the first half-bridge power chip and the first half-bridge lead-out area are connected through a bonding line, a gate electrode of the second half-bridge power chip and the second half-bridge lead-out area are connected through a bonding line.

In an embodiment of the present disclosure, the first half-bridge power chip and the second half-bridge power chip are connected to the first half-bridge lead-out area and the second half-bridge lead-out area, respectively, to form a signal control loop of the half-bridge power device.

In an embodiment of the present disclosure, the upper surface of the module substrate includes a first half-bridge area, a second half-bridge area, a first half-bridge lead-out area and a second half-bridge lead-out area, which are separate:
the upper surface of the module substrate includes a copper clad layer, the copper clad layer including a first half-bridge area, a second half-bridge area, a first half-bridge lead-out area and a second half-bridge lead-out area, which are separate.

In an embodiment of the present disclosure, a first end of the first power connector terminal is extended beyond the first end of the module substrate through a positive busbar, a second end of the second power connector terminal is extended beyond the second end of the module substrate, a second end of the third power connector terminal is extended beyond the first end of the module substrate;
the positive busbar is located above the third power connector terminal, and a second end of the positive busbar and the second end of the third power connector terminal have a first height difference.

In an embodiment of the present disclosure, the second end of the positive busbar has a first weld spot used for connection to a lead frame corresponding to the DC positive electrode (DC+) by welding; the first end of the positive busbar is connected to the first end of the first power connector terminal by welding.

The second end of the third power connector terminal has a second weld spot used for connection to a lead frame corresponding to the DC negative electrode (DC−) by welding. The second end of the second power connector terminal is used for connection to a lead frame corresponding to the alternating current (AC) output terminal.

In an embodiment of the present disclosure, the materials used for the power connector terminals include copper.

In an embodiment of the present disclosure, the materials used for the module substrate include active metal brazing (AMB) ceramic substrate or direct bonding copper (DBC) ceramic substrate.

The present disclosure further provides a half-bridge power module assembly comprising a plurality of parallelly connected half-bridge power devices as described in any of the above.

In comparison with the prior art, the present disclosure has the following advantages: the half-bridge power device of the scheme according to the present disclosure has a reduced busbar length and reduced loop inductance, thereby increasing the power density of the module and reducing the layout difficulty of half-bridge power module assembly. The scheme according to the present disclosure is also conducive to balancing internal drive consistency between the upper and lower bridge modules. Moreover, there is no need to increase module width—this is not only conducive to having a parallel connection of discrete half-bridge power devices, but also to reducing the number of laminated busbars, reducing assembly difficulties and the number of weld spots, increasing production speed and improving welding quality.

The accompanying drawings are intended to provide a further understanding of this disclosure, and they are included as an integral part of this disclosure. The accompanying drawings illustrate embodiments associated with this disclosure and serve to explain the principles associated with this disclosure together with the description.

### BRIEF DESCRIPTION OF THE DRAWINGS

FIG. 1 is a structural schematic diagram of a half-bridge power device of an embodiment of the present disclosure.

FIG. 2 is a structural schematic diagram of a half-bridge power device of an embodiment of the present disclosure.

FIG. 3 is a composition diagram of a half-bridge power module assembly of an embodiment of the present disclosure.

FIG. 4 is a schematic diagram of a half-bridge power module assembly circuit.

FIG. 5 is a structural schematic diagram of a half-bridge power device of an embodiment of the present disclosure.

FIG. 6 is a structural schematic diagram of a half-bridge power device of an embodiment of the present disclosure.

FIG. 7 is a structural schematic diagram of a half-bridge power module assembly.

FIG. 8 is a partial structural schematic diagram of a half-bridge power device.

FIG. 9 is a structural schematic diagram of a half-bridge power device.

FIG. 10 is a structural schematic diagram of a half-bridge power device.

### DETAILED DESCRIPTION

To provide a clearer explanation of the technical scheme of the embodiments of the present disclosure, a brief introduction to the accompanying drawings required in the description of the embodiments will be given below. Apparently, the drawings described below are merely some examples or embodiments of the present disclosure, and for persons of ordinary skill in the art, this disclosure can be used for other similar scenarios without innovative labor based on these accompanying drawings. Unless it is evident from the lingual context or otherwise stated, identical numerals used in the drawings represent the same structure or operation.

As shown in this disclosure and the claims, unless the context otherwise expressly indicates, the terms “a”, “one”, “a kind of” and/or “that” do/does not specifically refer to singular but may instead include plural. Generally, the terms “includes” and “comprises” only hint of including clearly identified steps and elements, and these steps and elements do not constitute an exclusive listing and the methods or equipment may also include other steps or elements.

Unless otherwise specifically stated, the relative layouts, numeric expressions and numerical values of the components and steps set forth in these embodiments do not limit the scope of this disclosure. Moreover, it should be understood that for ease of description, the sizes of the various parts shown in the accompanying drawings are not drawn according to scale. While technologies, methods and equipment known to persons skilled in the art may not be discussed in detail herein, the technologies, methods and equipment should be considered a part of the description where appropriate. In all the examples shown and discussed herein, any specific values should be construed as being merely exemplary rather than limiting. Therefore, the exemplary embodiments and other examples may have different values. It should be noted that similar numerals and alphabetic letters in the accompanying drawings represent similar items, so once a certain item is defined in a drawing, that item need not be further discussed with reference to subsequent drawings.

With regard to the description made in this disclosure, it should be understood that the directional or positional relationships indicated by directional terms such as “in front of, behind, upper, lower, left, right”, “lateral, vertical, perpendicular, horizontal” and “top, bottom” are usually based on the directional or positional relationships shown in the accompanying drawings which are merely intended for the convenience of describing this disclosure and simplifying the description. Without any explanation to the contrary, these directional terms do not indicate or imply the devices or elements referred to must have a specific direction and position or be constructed and operated in a specific direction and position, therefore these directional terms cannot be construed as limiting the scope of protection sought by this disclosure. The directional terms “internal, external” refer to the contour of a component relative to its inside and outside.

For ease of description, spatial relative terminologies such as “on top of . . . ”, “above . . . ”, “on the upper surface of” or “upper” may be used herein to describe the spatial-positional relationships between a device or feature and other devices or features. It should be understood that these spatial relative terminologies are intended to include different directions and positions in use or operation—in addition to the directions and positions of the devices described in the drawings. For example, if the devices in a figure are inverted, then the components described as being “above other devices or structures” or “on top of other devices or structures” will subsequently be positioned as “below other devices or structures” or “under other devices or structures”, respectively. Therefore, the example term “above” may include both orientations “above” and “below” The device may also be positioned in different ways (rotated by 90 degrees or in other directions) to provide a relevant explanation for the description of spatial relativity used herein.

Moreover, the use of the terms “first”, “second” and the like herein to define components is merely intended for the purpose of differentiating those components, and unless otherwise stated, those terms have no special meanings and should therefore not be construed as limiting the scope of protection sought by this disclosure. Also, while the terms used herein are selected from well-known and commonly used terms, some terms mentioned in the description herein may have been chosen by the applicant based on his/her judgment, and their detailed meanings are explained in the relevant sections hereof. Furthermore, it is requested that this disclosure be understood not only through the terms actually used, but also through the meaning implied by each term.

It must also be understood that when a component is referred to as being “on another component”, “connected to another component”, “coupled to another component” or “in contact with another component”, the component may be directly placed on top of that another component, connected or coupled to, or in contact with another component, or may be saved in an insert component. By contrast, when a component is referred as being “disposed directly on another component”, “directly connected to another component”, “directly coupled to another component” or “in direct contact with another component”, the component is not saved in an insert component. Similarly, when a first component is referred to as “in electrical contact with” or “electrically coupled to” a second component, there is an electric path that allows current to flow between the first component and the second component. The electric path may include capacitors, coupled inductors and/or other components that allow current to flow, even without direct contact between the conductive components.

An embodiment of this disclosure describes a half-bridge power module and a half-bridge power module assembly.

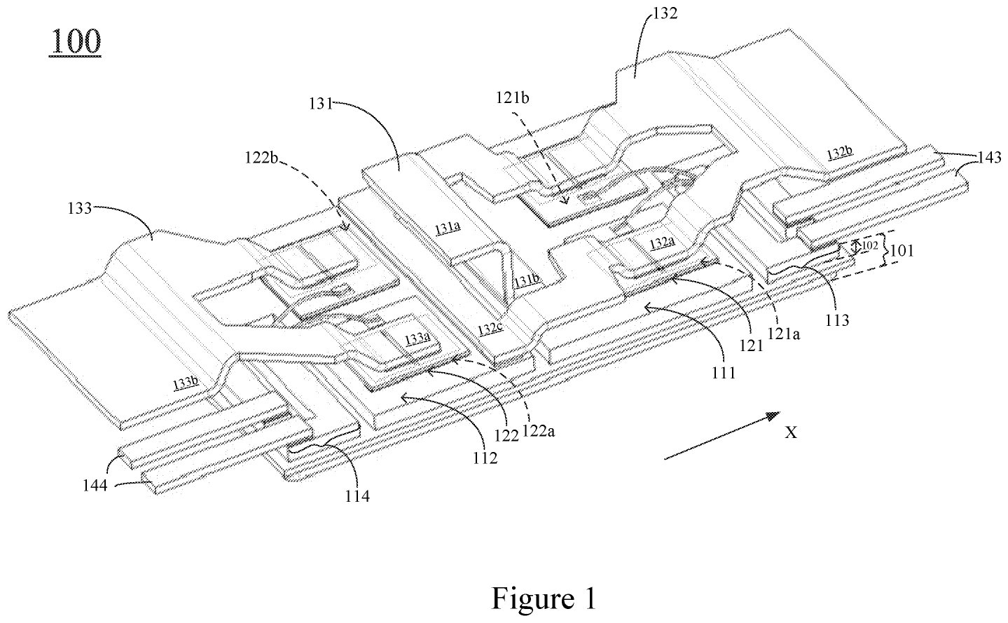

FIG. 1 is a structural schematic diagram of a half-bridge power device of an embodiment of the present disclosure.

Referring to FIG. 1, a half-bridge power device 100 comprises a module substrate 101, half-bridge power chips and power connector terminals.

In some embodiments, the upper surface of the module substrate 101 includes a copper clad layer 102. The copper clad layer 102 includes a first half-bridge area 111, a second half-bridge area 112, a first half-bridge lead-out area 113 and a second half-bridge lead-out area 114, which are separate. The first half-bridge lead-out area 113 and the second half-bridge lead-out area 114 are located at the ends of the module substrate 101, respectively.

Half-bridge power chips include a first half-bridge power chip 121 and a second half-bridge power chip 122. The first half-bridge power chip 121 and the second half-bridge power chip 122 are pasted to the first half-bridge area 111 and the second half-bridge area 112, respectively.

Power connector terminals include a first power connector terminal 131, a second power connector terminal 132 and a third power connector terminal 133. The first power connector terminal 131, the second power connector terminal 132 and the third power connector terminal 133 are connected to the first half-bridge area 111, the second half-bridge area 112, the first half-bridge power chip 121 and the second half-bridge power chip 122 to form a power loop of the half-bridge power device 100.

The first half-bridge power chip 121 and the second half-bridge power chip 122 are connected to the first half-bridge lead-out area 113 and the second half-bridge lead-out area 114, respectively, to form a signal control loop of the half-bridge power device 100.

In some embodiments, the power loop of the half-bridge power device 100 formed by the connection of the first power connector terminal 131, the second power connector terminal 132 and the third power connector terminal 133 to the first half-bridge area 111, the second half-bridge area 112, the first half-bridge power chip 121 and the second half-bridge power chip 122 includes:

a first end 131a of the first power connector terminal 131 is connected to a DC positive electrode (DC+), a second end 131b of the first power connector terminal 131 is connected to the first half-bridge power area 111 and also connected to a drain electrode of the first half-bridge power chip 121.

a first end 132a of the second power connector terminal 132 is connected to a source electrode of the first half-bridge power chip 121, a second end 132b of the second power connector terminal 132 serves as an alternating current (AC) output terminal of the half-bridge power device 100, a third end 132c of the second power connector terminal 132 is connected to the second half-bridge area 112 and also connected to a drain electrode of the second half-bridge power chip 122.

a first end 133a of the third power connector terminal 133 is connected to a source electrode of the second half-bridge power chip 122, a second end 133b of the third power connector terminal 133 is connected to a DC negative electrode (DC−).

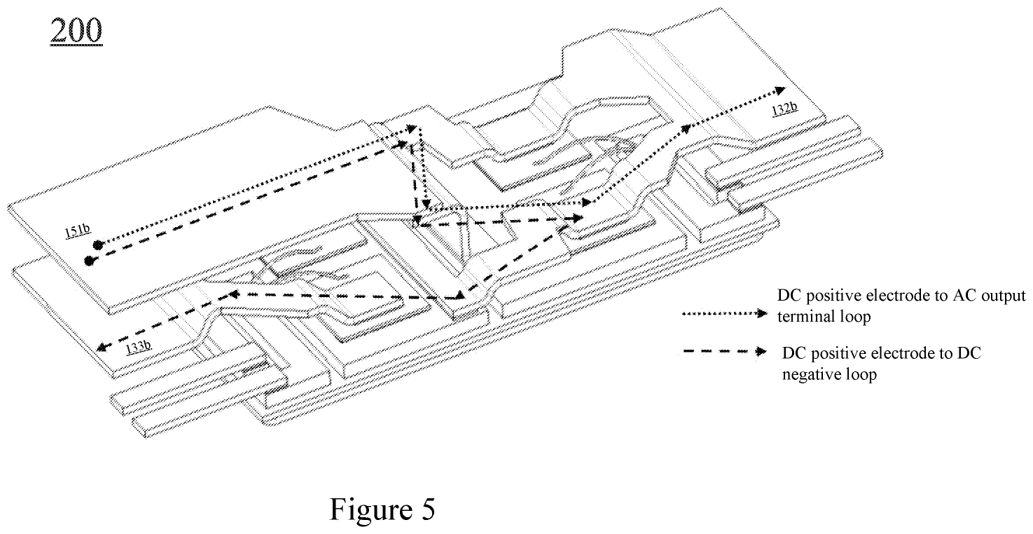

FIG. 5 is a structural schematic diagram of a half-bridge power device of an embodiment of the present disclosure. FIG. 5 shows a schematic flow direction of a current loop in a half-bridge power device 200, passed through from a DC positive electrode (DC+) to an alternating current (AC) output terminal, and a schematic flow direction of a current loop in the half-bridge power device 200, passed through from the DC positive electrode (DC+) to an DC negative electrode (DC−). Please refer to the legend and arrow markings in FIG. 5 for specific details.

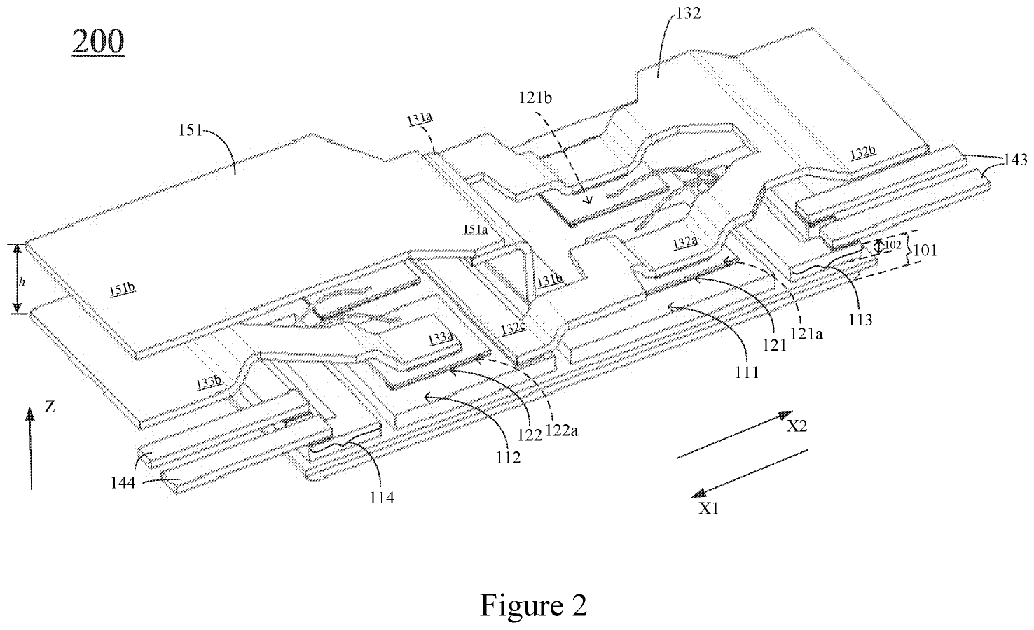

FIG. 2 is a structural schematic diagram of a half-bridge power device of an embodiment of the present disclosure.

Referring to both FIG. 2 and FIG. 5, an electrical signal of the DC positive electrode (DC+) first passes through a positive busbar 151 and is connected to the first half-bridge area 111 and also connected to the drain electrode of the first half-bridge power chip 121, along with the first power connector terminal 131. Then, the source electrode of the first half-bridge power chip 121 is led out through the first end 132a of the second power connector terminal 132, and one way is to be transmitted to the second end 132b of the second power connector terminal 132 as an alternating current (AC) output of the half-bridge power device 200. When a plurality of half-bridge power devices form a three-phase half-bridge power module assembly, it can also be known as an alternating current (AC) phase output terminal.

The source electrode of the first half-bridge power chip 121 is led out through the first end 132a of the second half-bridge power chip 122, and another way is to be transmitted to the third end 132c of the second power connector terminal 132, which is connected to the second half-bridge area 112 and also connected to the drain electrode of the second half-bridge power chip 122. Then, the source electrode of the second half-bridge power chip 122 is led out through the first end 133a of the third power connector terminal 133 and transmitted to the second end 133b of the third power connector terminal 133 as an electrical signal of the DC negative electrode (DC−) of the half-bridge power device 200.

In some embodiments, when the first half-bridge power chip 121 includes a plurality of first chips, the first end of the second power connector terminal is divided into multiple connecting pins which are connected to the source electrodes of the plurality of first chips, respectively. The connection location between the second end of the first power connector terminal 131 and the first half-bridge power area 111 is situated in an area between two connecting pins among the multiple connecting pins.

For example, in FIG. 1, the first half-bridge power chip 121 includes two first chips 121a, 121b, the first end of the second power connector terminal is divided into two connecting pins that are connected to the source electrodes of the first chips 121a, 121b. The connection location between the second end of the first power connector terminal 131 and the first half-bridge power area 111 is situated in an area between two connecting pins.

In some embodiments, when the second half-bridge power chip 122 includes a plurality of second chips, the first end of the third power connector terminal 133 is divided into multiple connecting pins which are connected to the source electrodes of the plurality of second chips.

For example, in FIG. 1, the second half-bridge power chip 122 includes two second chips 122a, 122b, the first end of the third power connector terminal 133 is divided into multiple connecting pins which are connected to the source electrodes of the two second chips 122a, 122b.

In some embodiments, the connection of the first half-bridge power chip 121 and the second half-bridge power chip 122 to the first half-bridge lead-out area 113 and the second half-bridge lead-out area 114, respectively, includes:
a gate electrode of the first half-bridge power chip 121 and the first half-bridge lead-out area 113 are connected through a bonding line, a gate electrode of the second half-bridge power chip 122 and the second half-bridge lead-out area 114 are connected through a bonding line. The bonding lines are, for example, aluminum wires. The first half-bridge lead-out area 113 is provided, for example, with a corresponding lead-out terminal 143, and the second half-bridge lead-out area 114 is provided, for example, with a corresponding lead-out terminal 144.

Referring to FIG. 2, in the structure of the half-bridge power device 200, the first end 131a of the first power connector terminal 131 is extended beyond a first end of the module substrate 101, the second end 132b of the second power connector terminal 132 is extended beyond a second end of the module substrate 101, and the direction of extension is, for example, along a first horizontal direction X1. The second end 133b of the third power connector terminal 133 is extended beyond the first end of the module substrate 101, and the direction of extension is, for example, along a second horizontal direction X2. The positive busbar 151 is located above the third power connector terminal 133, and a second end 151b of the positive busbar 151 and the second end 133b of the third power connector terminal 133 have a first height difference h. The first height difference h is in the vertical direction Z.

In some embodiments, the second end 151b of the positive busbar 151 has a first weld spot used for connection to a lead frame corresponding to the DC positive electrode (DC+) by welding. The first end 151a of the positive busbar 151 is connected to the first end 131a of the first power connector terminal 131 by welding, and the specific solder location may be referred to as a middle weld spot.

The second end 133b of the third power connector terminal 133 has a second weld spot used for connection to a lead frame corresponding to the DC negative electrode (DC−) by welding. The extension portion of the second end 133b of the third power connector terminal 133 can also serve as a negative busbar.

The second end 132b of the second power connector terminal 132 is used for connection to a lead frame corresponding to the alternating current (AC) output terminal.

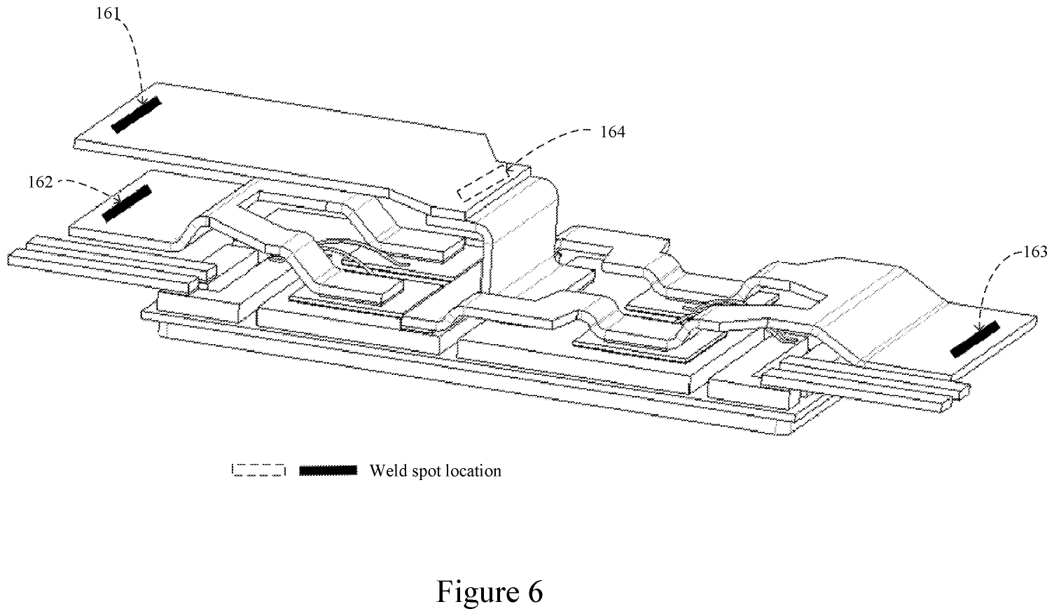

FIG. 6 is a structural schematic diagram of a half-bridge power device of an embodiment of the present disclosure. In FIG. 6, the location of a first weld spot 161, the location of a second weld spot 162 and the location of a third weld spot 163 are marked. FIG. 6 also shows the location of the middle weld spot 164. As mentioned above, the middle weld spot connects the second end of the positive busbar 151 and the first end of the first power connector terminal by welding to achieve electrical connection. Laser welding seam indicates the area where laser weld is located.

In some embodiments, the materials used for the power connector terminals include copper. The material used for the positive busbar may also be copper. The materials used for the module substrate 101 include active metal brazing (AMB) ceramic substrate or direct bonding copper (DBC) ceramic substrate.

This disclosure further provides a half-bridge power module assembly.

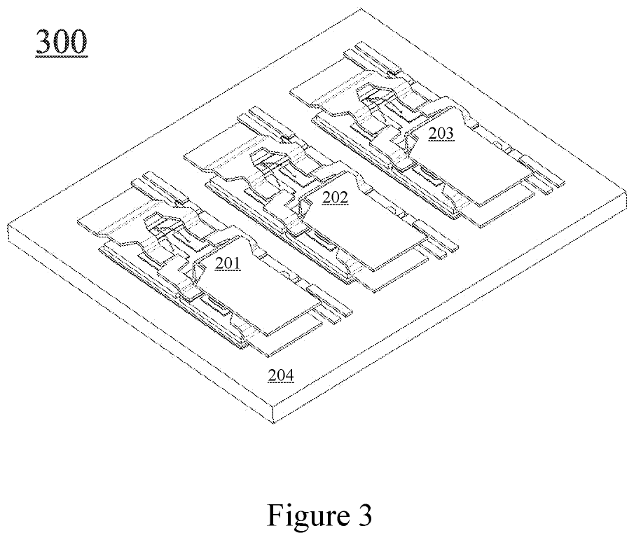

FIG. 3 is a composition diagram of a half-bridge power module assembly of an embodiment of the present disclosure.

Referring to FIG. 2, the half-bridge power module assembly 300 comprises a plurality of parallelly connected half-bridge power devices—specifically, for example, a half-bridge power device 201, a half-bridge power device 202 and a half-bridge power device 203. The half-bridge power device 201, the half-bridge power device 202 and the half-bridge power device 203 are installed on, for example, a radiator board or circuit board 204. Specific compositional structure of the half-bridge power device is as described above, for example.

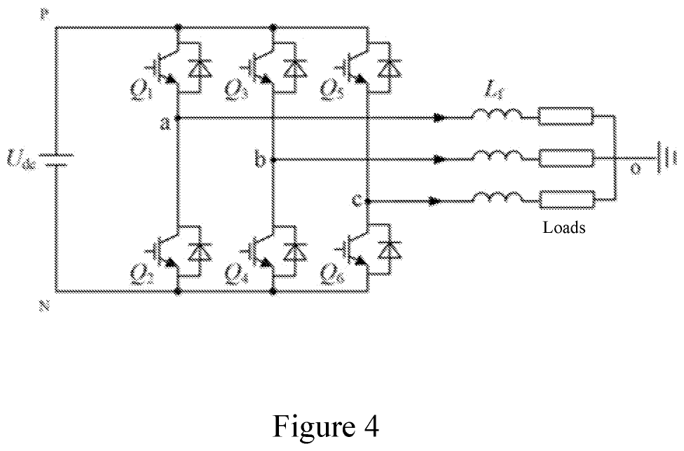

FIG. 4 is a schematic diagram of a half-bridge power module assembly circuit, and more specifically, also known as a three-phase half-bridge power module assembly circuit.

In the half-bridge power device of the present disclosure, the first half-bridge power chip, for example, corresponds to the first power tube Q1 shown in FIG. 4, the second half-bridge power chip, for example, corresponds to the second power tube Q2 shown in FIG. 4. In FIG. 4, the branch circuit in which the first power tube Q1 is located is referred to as an upper bridge arm, and the branch circuit in which the second power tube Q2 is located is referred to as a lower bridge arm. In the half-bridge power device shown in FIG. 1 or FIG. 2, the first half-bridge power chip can also be referred to as an upper bridge power chip, the second half-bridge power chip can also be referred to as a lower bridge power chip, the first half-bridge area can also be referred to as an upper bridge area, and the second half-bridge area can also be referred to as a lower bridge area. Accordingly, the first power connector terminal, the second power connector terminal and the third power connector terminal are connected to the upper bridge power chip (located in the upper bridge area), the lower bridge power chip (located in the lower bridge area) to form a power loop of the half-bridge power device. The power tube structure shown in FIG. 4 is merely illustrative and does not define the specific type of the power tubes, and different types of power tubes correspond to different half-bridge power chips.

The three half-bridge power devices 201, 202 and 203 in FIG. 3 can form, for example, a three-phase half-bridge power module assembly (FIG. 3 actually shows the power module part of the three-phase half-bridge power module assembly without showing the remaining portions). In practical electrical applications, higher power half-bridge power module assemblies can be formed by having a higher number of half-bridge power devices arranged in parallel.

For clearer elaboration of the technical effects of the technical scheme of the present disclosure, a comparative explanation of the compositional structure of a half-bridge power device is provided below.

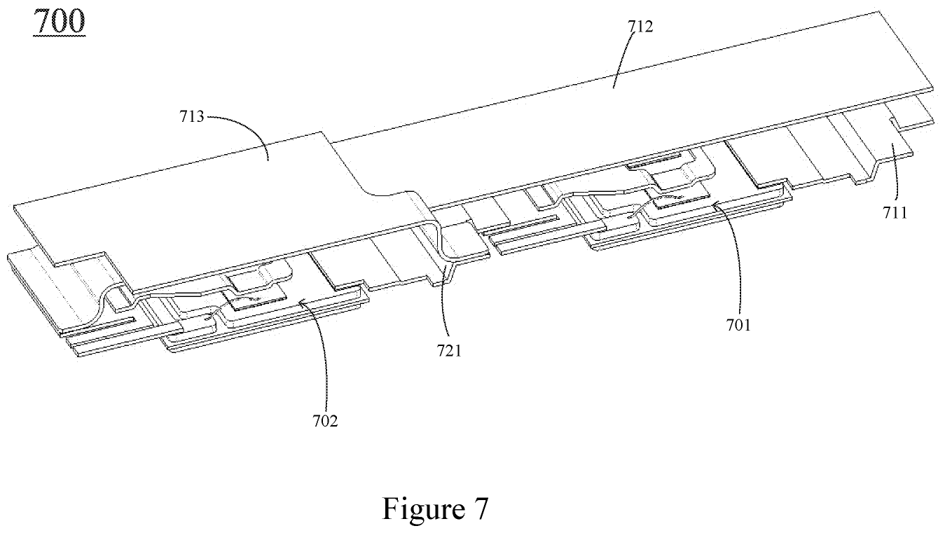

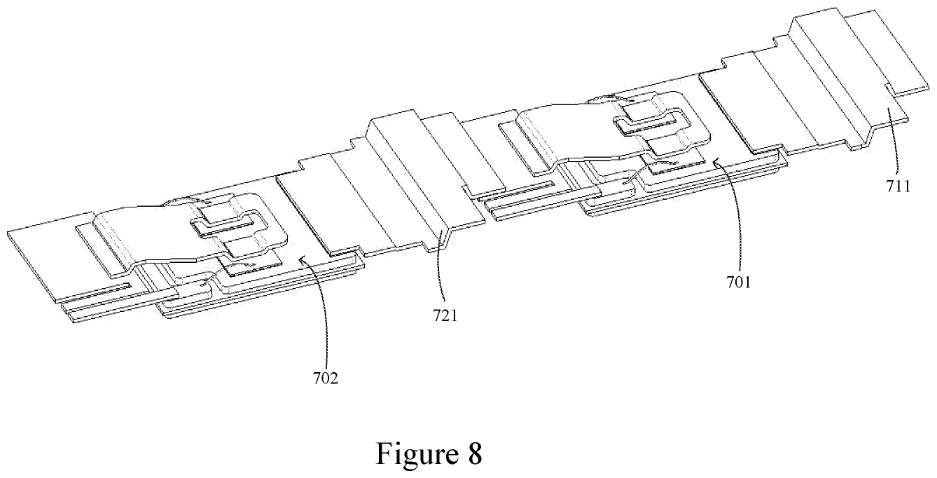

FIG. 7 is a structural schematic diagram of a half-bridge power module assembly. FIG. 8 is a partial structural schematic diagram of the half-bridge power module assembly shown in FIG. 7.

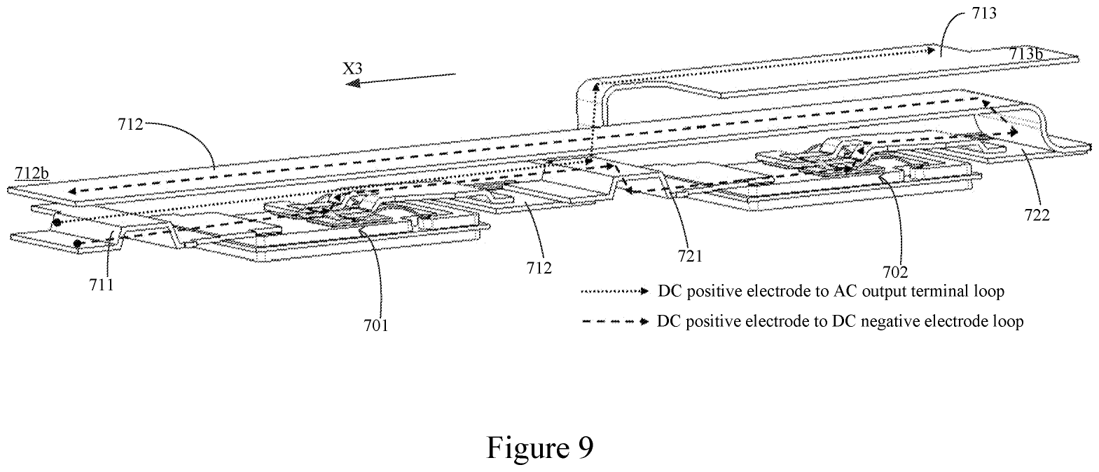

FIG. 9 is a structural schematic diagram of the half-bridge power module assembly shown in FIG. 7, from another perspective.

Referring to FIGS. 7 through 9, the half-bridge power module assembly 700 comprises an upper bridge module 701 and a lower bridge module 702. The upper bridge module 701 and the lower bridge module 702 require to form a half-bridge power module assembly by welding of the connector terminals—specifically, for example, by welding of the output terminal 712 of the upper bridge module 701 and the input terminal 721 of the lower bridge module 702 to achieve electrical connection, and to form a half-bridge power module assembly. Welding of the output terminal 712 of the upper bridge module 701 and the input terminal 721 of the lower bridge module 702 corresponds to a sixth weld spot.

FIG. 9 also illustrates a directional schematic of a circuit loop of a half-bridge power device. Referring to FIG. 8, the electrical signal connected to the DC positive electrode (DC+) by an input terminal 711 of the upper bridge module 701 passes through the first half-bridge module 701 and the second half-bridge module 702 to the output terminal 722 of the second half-bridge module 702, then passes through the busbar 712 to form a transmission loop, and a second end 712b of the busbar 712 is made to serve as a connector terminal of the DC negative electrode (DC−). The busbar 712 has to have a longer length in a horizontal direction X3 in order to stretch across the upper bridge module 701 and the lower bridge module 702. The first end of the busbar 712 and the output terminal 722 of the second half-bridge module 702 are welded to achieve electrical connection corresponding to a seventh weld spot.

The input terminal 721 of the second half-bridge module 702 will also lead out a single-channel signal through a busbar 713, and make a second end 713b of the busbar 713 serve as an alternating current (AC) output terminal of the half-bridge power module assembly 700. The busbar 713 is connected to the input terminal 721 of the second half-bridge module 702 by welding, and accordingly has an eighth weld spot.

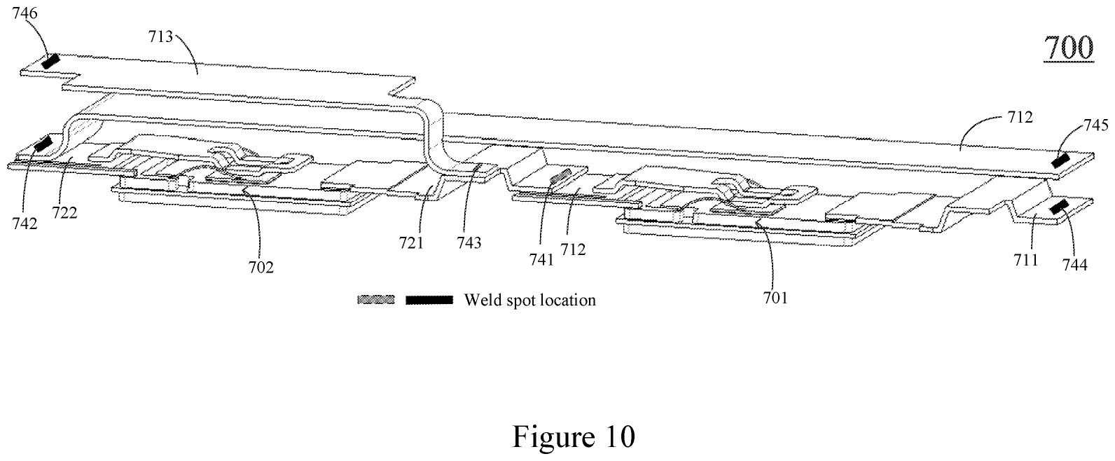

FIG. 10 is a structural schematic diagram of the half-bridge power device shown in FIG. 7, from another perspective. The location of the sixth weld spot is marked, for example, as 741 in FIG. 10. The location of the seventh weld spot is marked, for example, as 742 in FIG. 10. The location of the eighth weld spot is marked, for example, as 743 in FIG. 10. Part of the area surrounding the eighth weld spot is blocked by the busbar 712.

Continue referring to FIG. 10, a first end of the input terminal 711 of the upper bridge module 701 of the half-bridge power module assembly 700 is provided with a ninth weld spot 744 used for connection to a lead frame corresponding to the DC positive electrode (DC+) by welding. A second end of the busbar 712 is provided with a tenth weld spot 745 used for connection to a lead frame corresponding to the DC negative electrode (DC−) by welding. A second end of the busbar 713 is provided with an eleventh weld spot 746 used for connection to a lead frame corresponding to the alternating current (AC) output terminal.

In the scheme associated with a half-bridge power device shown in FIGS. 7 through 10, the upper bridge module and the lower bridge module are connected in series to form a half-bridge power device, a negative busbar corresponding to the DC negative electrode (DC−) needs to be connected to the corresponding lead frame through a longer path, the stray inductance caused is greater and the longer lengths of connection between the upper and lower bridges and the busbar also introduce greater stray inductance. Moreover, as the connector terminals of the DC+ and DC− are separately located at the ends of the half-bridge power module assembly 700 and the alternating current (AC) phase output terminal is located at the central portion of the module assembly 700, design complexity of laminated busbars is resulted, leading to difficulties in laser welding and longer laminated busbar length. Seismic resistance is also weaker due to longer busbar length.

In the technical scheme of the present disclosure, referring to FIGS. 1, 2, 5 and 6, the upper and lower bridge modules of the half-bridge power device 200 are integrated (i.e. on a substrate) and the routing length is reduced through changing the busbar power loop, thereby reducing stray inductance. Further, after changing the busbar power loop, the connector terminals of the DC+ and DC− are located on the same side of the half-bridge power device 200, and the alternating current (AC) phase output terminal is located on the other side of the half-bridge power device 200. This helps to avoid crisscross between busbars, significantly reduce design complexity of laminated busbars and simplify assembly process, making corresponding laser welding processes simpler and easier. The connector terminals of the DC+ and DC− are vertically stacked spatially, causing the magnetic fields generated by the current cancel each other, thereby improving the parasitic parameters of the device.

In the half-bridge power device of the present disclosure, the length of the busbars and loop inductance are reduced, and the peak voltage Vds and switching loss of the module are improved. Also, size is reduced and space saved, and connection of a larger number of power devices in parallel suitable for higher power applications is allowed. Specifically, according to the formula Ls*d(Id)/dt=Vds (where Ls denotes loop inductance), the greater the inductance of the drain electrode and source electrode, the higher the peak voltage Vds will be. Moreover, since switching loss Esw=∫(Vds*Id), the switching loss Esw increases as Vds increases. Therefore, the technical scheme of the present disclosure significantly improves peak voltage and switching loss by reducing busbar length and loop inductance of the half-bridge power device.

In comparison with the schemes shown in FIGS. 7 to 10, the length of the half-bridge power device of the present disclosure is reduced by at least one third (⅓), and this increases the power density of the module and reduces the layout difficulties of the half-bridge power module assembly. Drive-signal terminals (i.e. connector terminals of the signal control loop) are distributed on both sides of the upper and lower bridge modules, and this is conducive to balancing internal drive consistency of the upper and lower bridge modules. Moreover, there is no need to increase module width—this is not only conducive to having a parallel connection of discrete half-bridge power devices, but also to reducing the number of laminated busbars, reducing assembly difficulties and the number of weld spots, increasing production speed and improving welding quality. After reducing the length of the busbars, the seismic resistance of the half-bridge power module assembly is strengthened.

From the perspective of process technology, it can be seen that the technological processes of the scheme of the present disclosure meet the requirements of conventional production process, and the manufacturability of its design can be met. Compared against the scheme shown in FIGS. 7 through 10, the required area of the module substrate is reduced, the area of contact between the power device and the radiator board is reduced, the usage of intermediate connector layers (sintered silver or welding flux) is correspondingly reduced, and cost is thereby saved. Moreover, the design of the half-bridge power device helps to reduce manufacturing difficulties, thereby increasing the UPH (unit per hour) value.

With the foregoing having described the basic concepts, it is apparent to persons skilled in the art that the above disclosure is merely intended to be exemplary and should not constitute a limitation on the present disclosure. While it is not explicitly stated herein, various modifications, improvements and revisions may be made by persons skilled in the art to the present disclosure. Given that such modifications, improvements and revisions are proposed in the present disclosure, these modifications, improvements and revisions are still within the spirit and scope of the exemplary embodiments stated in this disclosure.

Moreover, specific terms are used herein to describe embodiments of this disclosure. For example, “one embodiment”, “an embodiment” and/or “some embodiments” are/is intended to refer/refers to a certain characteristic, structure or feature in connection with at least one embodiment. It should therefore be emphasized and noted that the term “one embodiment” or “an embodiment” or “an alternative embodiment” mentioned twice or multiple times in different instances in this description does not necessarily refer to the same embodiment. Also, certain characteristics, structures or features in one or more embodiments of the present disclosure can be appropriately combined.

Similarly, it should be noted that for simplification of the expression of the disclosure to thereby facilitate better understanding of one or more embodiments of the present disclosure, in the foregoing description of the embodiments of the present disclosure, multiple characteristics are merged into one embodiment, accompanying drawing or the description thereof at times. However, this disclosure method does not necessarily mean that the characteristics required by the subject of this disclosure are more in number than those mentioned in the claims. In actuality, the characteristics of that embodiment are less in number than all the characteristics of the above disclosed individual embodiments.

While this disclosure has been described with reference to the current specific embodiments, it should be recognized by persons skilled in the art that the aforesaid embodiments are merely intended to describe this disclosure, and various equivalent changes or replacements may be made without departing from the spirit of the present disclosure. Therefore, any changes and variations made to the aforesaid embodiments without substantively departing from the spirit of this disclosure shall fall within the scope of the claims of the present disclosure.

1. A half-bridge power device comprising:
a module substrate, an upper surface of the module substrate including a first half-bridge area, a second half-bridge area, a first half-bridge lead-out area, and a second half-bridge lead-out area, which are separate, wherein the first half-bridge lead-out area and the second half-bridge lead-out area are located at ends of the module substrate, respectively;
a plurality of half-bridge power chips, including a first half-bridge power chip and a second half-bridge power chip, the first half-bridge power chip and the second half-bridge power chip being connected to the first half-bridge area and the second half-bridge area, respectively;
a plurality of power connector terminals, including a first power connector terminal, a second power connector terminal, and a third power connector terminal, the first power connector terminal, the second power connector terminal, and the third power connector terminal being connected to the first half-bridge area, the second half-bridge area, the first half-bridge power chip, and the second half-bridge power chip to form a power loop of the half-bridge power device;
wherein a first end of the first power connector terminal is connected to a DC positive electrode (DC+) through a positive busbar and extended beyond a first end of the module substrate, wherein a second end of the third power connector terminal is connected to a DC negative electrode (DC−) and extended beyond a first end of the module substrate, and wherein the positive busbar is located above the third power connector terminal, and a second end of the positive busbar and the second end of the third power connector terminal have a first height difference.

2. The half-bridge power device according to claim 1,
wherein a second end of the first power connector terminal is connected to the first half-bridge area and also connected to a drain electrode of the first half-bridge power chip,
wherein a first end of the second power connector terminal is connected to a source electrode of the first half-bridge power chip, a second end of the second power connector terminal serves as an alternating current (AC) output terminal of the half-bridge power device, a third end of the second power connector terminal is connected to the second half-bridge area and also connected to a drain electrode of the second half-bridge power chip, and the second end of the second power connector terminal is extended beyond a second end of the module substrate, and
wherein a first end of the third power connector terminal is connected to a source electrode of the second half-bridge power chip.

3. The half-bridge power device according to claim 2,
wherein the first half-bridge power chip comprises a plurality of first chips,
wherein the first end of the second power connector terminal is divided into multiple connecting pins which are connected to the source electrodes of the plurality of first chips, respectively, and
wherein a connection location between the second end of the first power connector terminal and the first half-bridge power area is situated in an area between two connecting pins among the multiple connecting pins.

4. The half-bridge power device according to claim 2,
wherein the second half-bridge power chip comprises a plurality of second chips,
wherein the first end of the third power connector terminal is divided into multiple connecting pins which are connected to the source electrodes of the plurality of second chips.

5. The half-bridge power device according to claim 1,
wherein the connection of the first half-bridge power chip and the second half-bridge power chip to the first half-bridge lead-out area and the second half-bridge lead-out area, respectively, comprises:
a gate electrode of the first half-bridge power chip and the first half-bridge lead-out area connected through a bonding line, and
a gate electrode of the second half-bridge power chip and the second half-bridge lead-out area connected through a bonding line.

6. The half-bridge power device according to claim 1,
wherein the first half-bridge power chip and the second half-bridge power chip are connected to the first half-bridge lead-out area and the second half-bridge lead-out area, respectively, to form a signal control loop of the half-bridge power device.

7. The half-bridge power device according to claim 1,
wherein the upper surface of the module substrate comprises a copper clad layer, the copper clad layer including the first half-bridge area, the second half-bridge area, the first half-bridge lead-out area, and the second half-bridge lead-out area, which are separate.

8. The half-bridge power device according to claim 1,
wherein the second end of the positive busbar has a first weld spot for connection to a lead frame corresponding to the DC positive electrode (DC+) by welding, wherein the first end of the positive busbar is connected to the first end of the first power connector terminal by welding, and
wherein the second end of the third power connector terminal has a second weld spot for connection to a lead frame corresponding to the DC negative electrode (DC−) by welding.

9. The half-bridge power device according to claim 1,
wherein the second end of the second power connector terminal is connected to a lead frame corresponding to the alternating current (AC) output terminal.

10. The half-bridge power device according to claim 1,
wherein materials used for the power connector terminals include copper.

11. The half-bridge power device according to claim 1,
wherein materials used for the module substrate include active metal brazing (AMB) ceramic substrate or direct bonding copper (DBC) ceramic substrate.

12. A half-bridge power module assembly comprising a plurality of parallelly connected half-bridge power devices according to claim 1.
